(19) United States
(12) Patent Application Publication
(10) Pub. No.: US 2014/0072721 A1
(43) Pub. Date: Mar. 13, 2014

(54) Method for Modifying a Surface of a Substrate using Ion Bombardment

(71) Applicants: Ulrike Schulz, Jena (DE); Peter Munzert, Jena (DE); Roland Thielsch, Dresden (DE); Waldemar Schoenberger, Dresden (DE); Matthias Fahland, Dresden (DE); Ronny Kleinhempel, Gelenau (DE)

(72) Inventors: Ulrike Schulz, Jena (DE); Peter Munzert, Jena (DE); Roland Thielsch, Dresden (DE); Waldemar Schoenberger, Dresden (DE); Matthias Fahland, Dresden (DE); Ronny Kleinhempel, Gelenau (DE)

(73) Assignee: SOUTHWALL EUROPE GMBH, Grossroehrsdorf (DE)

(21) Appl. No.: 14/005,239

(22) PCT Filed: Mar. 14, 2012
(86) PCT No.: PCT/EP2012/054480

§ 371 Date: Nov. 21, 2013

(30) Foreign Application Priority Data
Mar. 14, 2011 (DE) 10 2011 013 822.6

(51) Int. Cl. C23C 14/48; H01J 37/34

(52) U.S. Cl. CPC C23C 14/48; H01J 37/3405
USPC 427/523; 204/192.32

(57) ABSTRACT

A process is described for modification of a surface of a substrate by ion bombardment, in which the ions are produced by means of a magnetic field-assisted glow discharge in a process gas. The magnetic field-assisted glow discharge is produced by means of a magnetron having an electrode and at least one magnet for production of the magnetic field. The process gas has at least one electronegative constituent, such that negative ions are produced in the magnetic field-assisted glow discharge, and the negative ions which are produced at the surface of the electrode are accelerated in the direction of the substrate by an electrical voltage applied to the electrode.

This patent application is a national phase filing under section 371 of PCT/EP2012/054480, filed Mar. 14, 2012, which claims the priority of German patent application 10 2011 013 822.6, filed Mar. 14, 2011, each of which is incorporated herein by reference in its entirety.

### TECHNICAL FIELD

The invention relates to a process for modifying a surface of a substrate by ion bombardment, with which it is especially possible to produce a reflection reducing surface structure on polymer surfaces.

### BACKGROUND

It is known from International Patent Publication No. WO 97/48992 that the interfacial reflection of a surface of a polymer substrate can be reduced by applying an interference layer system composed of several thin transparent layers. Such interference layer systems are generally applied by vacuum coating processes, although application to large-area polymer substrates is technically complex because of the high demands on layer thickness accuracy. Moreover, it is difficult in the case of substrates made from polymers to ensure sufficient adhesion of the interference layer system, which is generally formed from oxidic materials.

An alternative means of reducing the interfacial reflection of a substrate made from a polymer is described in publication German Patent Publication No. DE 10241708 B4. In this process, a refractive index gradient layer produced at the surface of the polymer substrate by ion bombardment with an ion beam reduces the interfacial reflection of the surface of the polymer. The proposed treatment of the polymer surface with an ion beam, however, cannot be applied readily to large-area substrates, for example polymer films.

### SUMMARY OF THE INVENTION

Embodiments of the invention specify a process for modifying a surface of a substrate, especially of a polymer substrate, by ion bombardment, with which it is especially possible to achieve reduced interfacial reflection of the substrate, and the process should be suitable for treatment of large areas. More particularly, the process should be employable in what is called a roll-to-roll operation, in which the substrate, for example, in the form of a film, is unwound from a roll and wound onto another roll, and in this way is transported, preferably continuously, through the vacuum system provided for treatment of the surface.

In one configuration of the process for modifying a surface of a substrate by ion bombardment, the ions are produced by means of a magnetic field-assisted glow discharge in a process gas. The magnetic field-assisted glow discharge is advantageously produced by means of a magnetron having an electrode and at least one magnet for production of the magnetic field.

Such magnetrons are known per se and are used, for example, in magnetron sputtering systems for deposition of thin layers. The process described herein can therefore advantageously be implemented in existing vacuum coating systems.

In conventional magnetron sputtering, a plasma is produced by means of the magnetron, and the process gas used is typically a noble gas, especially argon. In magnetron sputtering, positive ions generated in the plasma are accelerated to the electrode, which is therefore also referred to as the target. The ions which hit the electrode knock atoms out of the electrode material, which are deposited on the substrate.

In contrast to magnetron sputtering as known per se, a process gas having at least one electronegative constituent is used in the process described herein, such that negative ions are produced in the magnetic field-assisted glow discharge.

At least some of the negative ions are produced at the surface of the electrode and accelerated in the direction of the substrate by an electrical voltage applied to the electrode. Preferably, the negative ions are accelerated by the electrode such that they hit the substrate with an energy of at least 100 eV.

The negative ions which hit the substrate bring about a modification of the surface thereof. More particularly, it is possible in this way to produce a reflection-reducing surface structure at the surface of the substrate. The ions which hit the surface of the substrate can especially bring about material removal therefrom, through which the surface of the substrate is roughened. This roughening brings about a refractive index gradient which reduces the reflection of the surface. It is alternatively also possible that the incoming ions are implanted into a near-surface region of the substrate, and a density and/or refractive index gradient is produced in this way.

The surface of the substrate is especially roughened by the ion bombardment, and it is advantageously possible by the process to produce comparatively deep structures. In an advantageous configuration, by means of the ion bombardment, a structure is produced at the surface of the substrate which extends at least 50 nm deep into the substrate. The nature of the structures produced at the surface of the substrate can be varied especially through a variation in the magnitude and the profile of the electrical voltage applied to the electrode of the magnetron against time.

The electrical voltage which is applied to the electrode for acceleration of the negative ions in the direction of the substrate is preferably a mid-frequency voltage. It has been found that the use of a mid-frequency voltage promotes the formation of negative ions at the surface of the electrode. More preferably, the mid-frequency voltage has a frequency between 1 kHz and 250 kHz.

As well as the achievement of a reflection-reducing effect on substrates, especially polymer substrates, the process can also be used for roughening of a surface for other purposes. The aim of the process may, for example, be an increase in the specific surface area or the increase in the absorption coefficient. The process can be averted to all substrates which can be removed effectively by electronegative ions. As well as plastics, this relates particularly to carbon.

The electronegative constituent of the process gas is preferably oxygen. In a further advantageous configuration of the process, the electronegative constituent used in the process gas is fluorine or chlorine. The use of oxygen, fluorine or chlorine is particularly advantageous, since these materials, according to the Pauling electronegativity scale, have the highest electronegativity among the chemical elements.

The electrode of the magnetron preferably comprises or consists of at least one of the elements Al, Mg, Si or Ti. The electrode may also comprise an alloy comprising at least one of these elements with a proportion by weight of at least 10%.

The magnetron may, for example, be a planar magnetron. In a planar magnetron, the electrode is essentially flat, which does not exclude the possibility that the surface of the electrode facing the plasma is not entirely planar because of a material removal through impacting ions.

In a preferred configuration, the magnetron has at least two planar magnetrons. For example, two planar magnetrons may be arranged alongside one another and in this way form a double magnetron. This allows larger substrates or larger partial areas of a substrate to be treated simultaneously. In addition, in the case of a moving substrate, the passage speed can advantageously be increased.

In a further advantageous configuration, the magnetron is a tubular magnetron. In this version, the electrode of the magnetron is executed in the form of a tube and is advantageously rotated about an axis of rotation of the tube in the process. The magnet system of the magnetron is preferably not moved in this case. The stationary magnetic field localizes the region in which the glow discharge takes place. In this region, the negative ions adsorbed on the electrode are accelerated in the direction of the substrate. As a result of the rotation of the electrode of the tubular magnetron, regions of the tubular electrode having adsorbed atoms of the electronegative constituent of the process gas are continuously rotated into the region of the discharge. In this way, a higher efficiency of the process can be achieved than in the case of use of a planar magnetron.

In an advantageous configuration of the process, the magnetron has at least two tubular magnetrons. More particularly, the magnetron may be a double magnetron having two tubular magnetrons. This enables the treatment of large-area substrates and/or the increase in the passage speed of a moving substrate.

In the process, no electrical voltage is applied to the substrate. More particularly, no electrical voltage is applied to any substrate holder used for the substrate either. The acceleration of the negative ions to the substrate is thus effected exclusively by the voltage applied to the electrode of the magnetron. The process is therefore especially suitable for electrically insulating substrates composed of electrically insulating polymers.

The substrate may especially be a polymer substrate. The process can advantageously be used for the modification of the surface of a multitude of polymers. More particularly, the substrate may comprise polyethylene terephthalate (PET), polycarbonate (PC), polymethylmethacrylate (PMMA), ethylene-tetrafluoroethylene (ETFE), polyethylene naphthalate (PEN) or triacetylcellulose (TAC).

In addition, the process has the advantage that the surface modification, especially the production of a reflection-reducing nanostructure at the surface of the substrate, can be achieved comparatively rapidly. Preferably, the surface of the substrate is irradiated with the ions for not longer than 200 s.

The process can advantageously be conducted in a vacuum system in which the substrate is moved continuously during the ion bombardment. Preferably, the substrate is moved at a speed of at least 1 m/min during the ion bombardment. The substrate is moved, for example, with a conveyor belt during the conduct of the process. The process can be performed especially in a vacuum system provided as a belt-coating system.

More particularly, it is possible by the process to treat large-area substrates, for example films, in a roll-to-roll process. In this case, the substrate is unwound from a roll and wound onto another roll, and in this way moved continuously through the ion beam produced in the process.

Advantageously, by means of the ion bombardment, a structure is generated at the surface of the substrate, and this produces a refractive index gradient in a direction running at right angles to the substrate surface. This means that the refractive index at the interface between the substrate and the surrounding medium does not change abruptly because of the structuring produced at the surface of the substrate, but forms a continuous transition. Preferably, the region of the refractive index gradient extends over a range of at least 50 nm in the direction at right angles to the surface of the substrate. A structure produced in this way by means of the ion bombardment, more particularly, reduces the reflection of the surface of the substrate. More particularly, the process is therefore suitable for rendering the surface of a substrate nonreflective, and it is also possible to treat large areas, for example, the surface of a polymer film, in a comparatively simple and inexpensive manner.

### BRIEF DESCRIPTION OF THE DRAWINGS

The invention is illustrated in detail hereinafter by exemplary embodiments in combination with FIGS. 1 to 4.

FIG. 1 is a schematic diagram of a cross section through an apparatus for performance of the process for modifying a surface of a substrate in a first exemplary embodiment;

FIG. 2 is a schematic illustration in the form of a graph of the profile of the voltage at the electrode against time in one exemplary embodiment;

FIG. 3 is a schematic diagram of a cross section through a surface structure obtained at the surface of the substrate in one exemplary embodiment; and

FIG. 4 is a schematic diagram of a cross section through an apparatus for performance of the process for modification of a surface of a substrate in a second exemplary embodiment.

Identical or equivalent constituents are each given the same reference numerals in the figures. The constituents shown and the size ratios of the constituents with respect to one another should not be regarded as being to scale.

### DETAILED DESCRIPTION OF ILLUSTRATIVE EMBODIMENTS

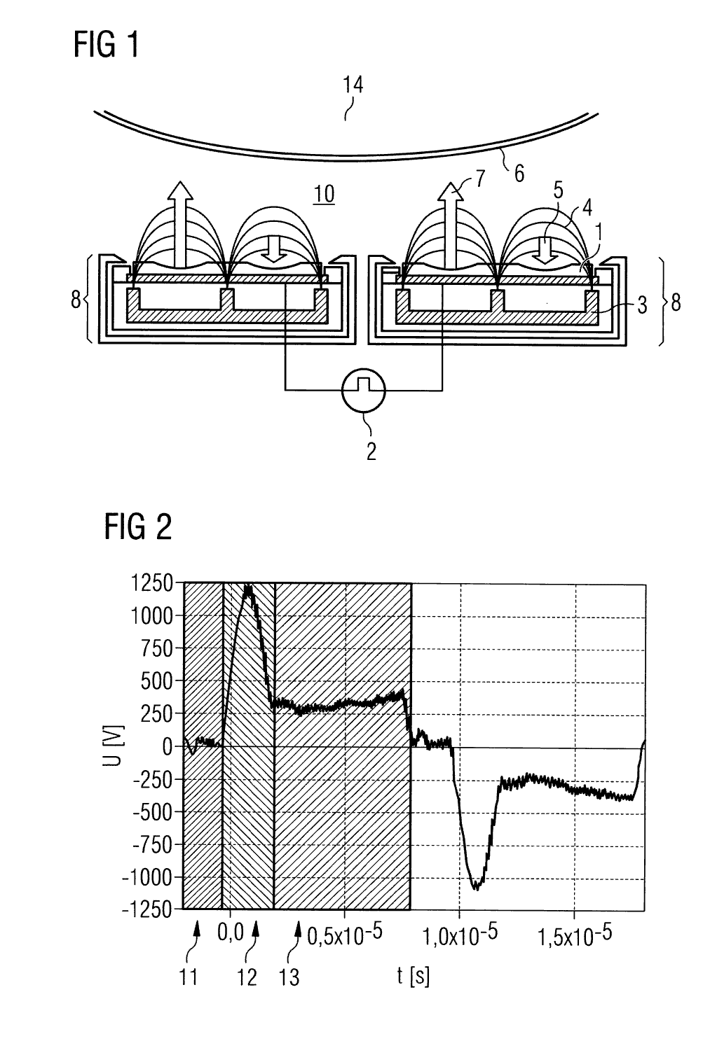

The apparatus shown in FIG. 1 for performance of the process for modification of the surface of a substrate 6 has an arrangement of two planar magnetrons 8. Each planar magnetron 8 has an electrode 1 connected to a mid-frequency voltage generator 2. In addition, each planar magnetron 8 contains magnets 3 which produce a magnetic field 4.

The process is performed in a vacuum system into which a process gas 10 is admitted. The process is advantageously suitable for treatment of large-area substrates 6. For example, the substrate 6 can be transported in the form of a film on a roll 14. The substrate 6 is preferably moved continuously past the magnetrons 8 at a distance during the performance of the process.

By means of the magnetrons 8, a magnetic field-assisted glow discharge is produced in the process gas 10 in the process. This produces a plasma in the process gas 10, and the magnetic fields 4 generated by the magnets 3 are intended to prevent diffusion of electrons out of the plasma.

In the magnetic field-assisted glow discharge, positive ions 5 are firstly produced in the process gas 10, and these are accelerated in the direction of the electrodes 1. The positive ions 5 are, for example, ions of a noble gas present in the process gas 10. The process gas 10 may comprise, for example, argon.

In the process described herein, the process gas 10 comprises at least one electronegative constituent. The electronegative constituent is preferably oxygen. Alternatively, the process gas 10 may, for example, also comprise fluorine or chlorine as the electronegative constituent. Oxygen, fluorine and chlorine feature particularly high electronegativity values. By virtue of the process gas 10 comprising at least one electronegative constituent, the magnetic field-assisted glow discharge gives rise to negative ions 7. Some of the negative ions are formed in the plasma. These negative ions generally have relatively low energies and therefore generally cannot leave the plasma. Further negative ions 7 are produced at the surface of the electrodes 1. These negative ions 7 are accelerated in the direction of the substrate 6 by an electrical voltage of preferably more than one hundred volts and advantageously serve in the process for modification of the surface of the substrate 6.

It has been found that the formation of negative ions 7 on the surface of the electrode 1 is promoted by operating the electrodes 1 with a mid-frequency voltage generator 2. The mid-frequency voltage has a frequency which is advantageously between 1 kHz and 250 kHz. For example, the frequency may be 100 kHz.

An illustrative profile of the discharge voltage U generated by the voltage generator 2 as a function of the time t is shown in FIG. 2. In a first time range 11 (the off phase), no voltage is applied to the electrodes 1, and the electrodes 1 within this time range are covered with the electronegative constituent of the process gas 10, for example, with oxygen atoms or molecules. In a second time range 12 (ignition phase), there is a distinct peak in the voltage, which leads to formation of high-energy ions having energies exceeding 1000 eV. In a third time range 13, called the work phase, there arises a discharge voltage of at least 100 V, preferably several hundred volts, with which the negative ions 7 are accelerated in the direction of the substrate 6.

The surface structure produced at the surface of the substrate 6 by the negative ions 7 accelerated in the direction of the substrate 6 depends on the durations of the individual time ranges 11, 12, 13 and can therefore be influenced particularly by a variation in the pulse parameters of the mid-frequency voltage produced with the voltage generator 2. The voltage profile shown in FIG. 2 was measured using an aluminum electrode 1. When other electrodes 1 are used, there is no change in the basic voltage profile, but there is a change in the magnitude of the voltage and the duration of the individual time ranges 11, 12, 13, such that it is possible through the use of various electrodes to produce various kinds of structures at the surface of the substrate 6.

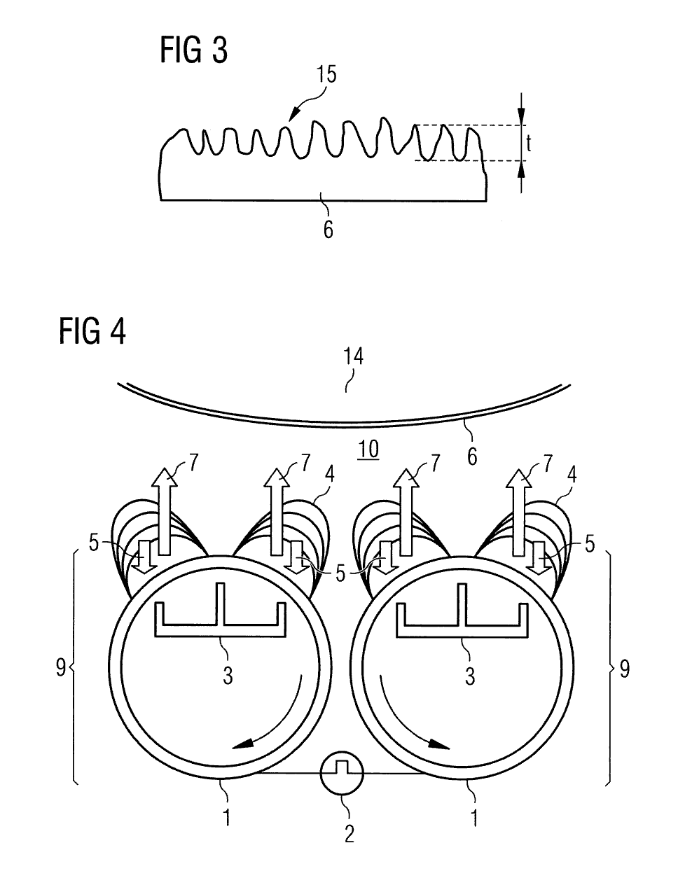

In the process, at the surface of the substrate 6, a surface structure 15 as shown by way of example in cross section in FIG. 3 is advantageously produced. The surface structure 15 preferably extends into the substrate 6 up to a depth t of at least 50 nm. More particularly, the surface structure 15 at the surface of the substrate 6 forms a refractive index gradient. This means that the refractive index at the interface between the substrate 6 and the surrounding medium does not have any abrupt change because of the surface structure 15, but changes continuously in the direction at right angles to the substrate surface over a region corresponding to the depth t of the surface structure 15. Such a refractive index gradient at the surface of the substrate 6 can especially reduce the reflection of the surface of the substrate 6.

The process described herein has the advantage that rendering the surface of a substrate 6 nonreflective in such a way can be achieved comparatively rapidly and inexpensively, more particularly also on large-area substrates. For example, it was possible to achieve lowering of the interfacial reflection in the course of treatment of polyethylene terephthalate (PET) as substrate material after a treatment time of only 30 seconds with movement of the substrate at a passage speed of 0.5 m/min in a belt-coating system.

FIG. 4 shows a further exemplary embodiment of an apparatus for performing the process in schematic cross section. In contrast to the exemplary embodiment shown in FIG. 1, two tubular magnetrons 9 are used to produce the magnetic field-assisted glow discharge. Each of the tubular magnetrons 9 has electrodes 1 in the form of cylindrical tubes which are preferably rotated about their principal axis during the performance of the process. The magnets 3 of the tubular magnetrons 9 are not moved and thus each generate a stationary magnetic field 4. As a result of the rotation of the tubular electrodes 1 about their principal axis, new regions of the electrode surfaces with absorbed atoms or molecules of the electronegative constituent of the process gas 10 are continuously transported into the region of the magnetic field 4 in which the magnetic field-assisted glow discharge takes place.

In this version, negative ions 7 are therefore produced particularly effectively at the surfaces of the electrodes 1, which are accelerated in the direction of the substrate 6.

In addition, this exemplary embodiment has the advantage that the number of negative ions 7 produced at the electrode surfaces 1 can be varied by a variation in the angular velocity of the rotation of the electrodes 1, and can thus be adjusted independently of the voltage profile. This especially enables the use of a comparatively simple voltage generator 2, which produces, for example, a sinusoidal profile of the discharge voltage.

Through a change in the alignment of the magnetic field 4 generated by the magnets 3, it is possible to adjust the spatial distribution of the negative ions 7 and the angular distribution thereof. Because of the rotation of the tubular electrodes 1, the surfaces of the electrodes 1 are worn away homogeneously, such that the spatial distribution and the angular distribution of the negative ions 7 are not altered significantly even in the case of a prolonged service life of the electrodes 1.

Through the use of several tubular magnetrons 9, it is possible to increase the passage speed of a moving substrate 6 in the course of ion bombardment. For example, through the simultaneous operation of four tubular magnetrons 9 at a passage speed of 2 m/min, through the treatment of one side of a PET substrate 6, an increase in transmission averaging 4% was achievable compared to the untreated substrate.

The invention is not restricted by the description of the exemplary embodiments. Instead, the invention encompasses every novel feature and every combination of features, which especially includes every combination of features in the claims, even if this feature or this combination itself is not specified explicitly in the claims or exemplary embodiments.

1-14. (canceled)

15. A process for making a device, the process comprising:
producing ions by means of a magnetic field-assisted glow discharge in a process gas; and
modifying a surface of a substrate by ion bombardment using the ions;
wherein the magnetic field-assisted glow discharge is produced using a magnetron having an electrode and a magnet to produce the magnetic field;
wherein the process gas has an electronegative constituent, such that negative ions are produced in the magnetic field-assisted glow discharge;
wherein the negative ions that are produced at the surface of the electrode are accelerated toward the substrate by an electrical voltage applied to the electrode;
wherein the negative ions that hit the substrate bring about the modification of the surface of the substrate; and
wherein the ion bombardment produces a surface structure at the surface of the substrate that extends at least 50 nm deep into the substrate.

16. The process according to claim 15, wherein the electrical voltage has a frequency between 1 kHz and 250 kHz.

17. The process according to claim 15, wherein the electronegative constituent of the process gas is oxygen.

18. The process according to claim 15, wherein the electronegative constituent of the process gas is fluorine or chlorine.

19. The process according to claim 15, wherein the electrode of the magnetron comprises at least one of the elements Al, Mg, Si or Ti or an alloy comprising at least one of these elements with a proportion by weight of at least 10%.

20. The process according to claim 15, wherein the magnetron has at least one planar magnetron.

21. The process according to claim 15, wherein the magnetron has at least one tubular magnetron.

22. The process according to claim 15, wherein no voltage is applied to the substrate during the ion bombardment.

23. The process according to claim 15, wherein the substrate comprises a polymer substrate.

24. The process according to claim 23, wherein the substrate comprises polyethylene terephthalate (PET), polycarbonate (PC), polymethylmethacrylate (PMMA), ethylene-tetrafluoroethylene (ETFE), polyethylene naphthalate (PEN) or triacetylcellulose (TAC).

25. The process according to claim 15, wherein the surface of the substrate is irradiated with the ions for not longer than 200 s.

26. The process according to claim 15, wherein the substrate is moved at a speed of at least 1 m/min during the ion bombardment.

27. The process according to claim 15, wherein the surface structure produced by the ion bombardment produces forms a refractive index gradient.

28. The process according to claim 15, wherein the surface structure produced by the ion bombardment reduces the reflection of the surface of the substrate.
